(19) United States
(12) Patent Application Publication
(10) Pub. No.: US 2020/0243791 A1
(43) Pub. Date: Jul. 30, 2020

(54) CAPPING LAYER PROCESS WITH LOW TEMPERATURE PHOTORESIST PATTERNING

(71) Applicant: Avalon Holographics Inc., St. John's (CA)

(72) Inventors: Jennifer Campbell, St. John's (CA); Andrew Ward, St. John's (CA); Tushar Shuvra Biswas, Edmonton (CA); Roksana Bavand, Edmonton (CA); Kathleen M. Krause, Edmonton (CA); Daniel Bachman, Edmonton (CA); Steven Rutledge, Edmonton (CA); Arash Mohammadpour, Edmonton (CA); Sonja Hanna-Quinn, St. John's (CA); Joshua Rideout, Vanier (CA)

(21) Appl. No.: 16/256,081

(22) Filed: Jan. 24, 2019

(51) Int. Cl. H01L 51/52; H01L 51/56; H01L 51/00

(52) U.S. Cl. CPC H01L 51/5228; H01L 51/0011; H01L 51/0021; H01L 51/56

(57) ABSTRACT

A method of photolithography patterning multi-colored organic light emitting diodes (OLED) for a sub 10 um pixel size range, suited for a high-definition light field display, on a single substrate with a multilayer capping layer by way of sputtering deposition for protection of organics with advanced adhesion to the substrate comprising the steps of depositing a first OLED with a capping layer then depositing a second OLED structure on the substrate using a low temperature photoresist patterning process with a capping layer.

### BACKGROUND

Current organic light emitting diode (OLED) fabrication methods for emissive display applications are suited for mass manufacturing, which can limit the reduction in the attainable pixel size. The use of shadow masks is commonly seen in fabrication of larger OLEDs; for the smaller scale appropriate for a high-definition light field display, photolithography can be used.

Sputter deposition is sometimes used to deposit one or more electrode layers, such as the top electrode, in OLED fabrication. Sputter deposition facilitates control of composition and is well suited for mass manufacturing. Sputter deposition can sometimes be damaging to the organic layers of the OLED.

### SUMMARY

The approaches described here are advantageous for high-definition light field display technology. The fabrication techniques described herein are suitable for OLED on a sub 10 μm pixel size. The protective capping layer protects the organic layers of the OLED structure and the low temperature photoresist patterning allows deposition of multiple colored OLEDs on a single substrate. For the purposes of a high definition, three-dimensional light field display, pixel size in the ˜10 μm range can be achieved and the ability to turn each pixel on individually can be implemented. The use of a protective capping layer in OLED fabrication is compatible with such submicron dimensions appropriate for OLED structures for a high resolution,

The present disclosure provides a process for fabricating multiple, differently colored sub 10 μm OLEDs on a single substrate with a capping layer with increased protection and adhesion due to sputter deposition.

According to an aspect there an organic light-emitting diode includes
i. a substrate;
ii. a first electrode disposed on the substrate;
iii. an organic light-emitting structure disposed on the first electrode;
iv. a multi-layer capping structure disposed over the organic light-emitting material, the multi-layer capping structure including a first conductive layer and a second conductive layer each having a lateral extent greater than a lateral extent of the organic light-emitting material.

Embodiments can include one or more of the following features.

In an embodiment of the organic light-emitting diode, the organic light-emitting structure comprises one or more layers of light-emitting material.

In an embodiment of the organic light-emitting diode, the first conductive layer of the capping structure comprises aluminum.

In an embodiment of the organic light-emitting diode, the second conductive layer of the capping structure comprises indium tin oxide (ITO).

In an embodiment of the organic light-emitting diode, a second electrode is disposed between the organic light-emitting structure and the capping structure.

In an embodiment of the organic light-emitting diode, the substrate is formed of a material transparent to one or more wavelengths of light emitted by the organic light-emitting structure.

In an aspect there is provided a method of making an organic light-emitting diode, the method including:
i. forming an electrode on a substrate;
ii. depositing an organic light-emitting structure on the first electrode; and
iii. depositing a multi-layer capping structure over the organic light emitting structure, including depositing a first conductive layer and a second conductive layer such that each of the first and second conductive layers has a lateral extent greater than a lateral extent of the organic light-emitting structure.

Embodiments can include one or more of the following features.

In an embodiment of the method, depositing a first conductive layer comprises depositing a layer of aluminum and in which depositing a second conductive layer comprises depositing a layer of indium tin oxide (ITO) onto the layer of aluminum.

In an embodiment of the method, depositing a multi-layer capping structure comprises depositing the first and second conductive layers by a sputtering process.

In an embodiment of the method, depositing the organic light-emitting structure is achieved by way of an evaporation process.

In an embodiment of the method, depositing a second electrode on the organic light-emitting structure.

In an embodiment of the method, depositing a second electrode on the organic light-emitting structure by an evaporation process.

In an embodiment of the method, an undercut photoresist structure is formed on the substrate, comprising depositing the organic light-emitting structure and the multi-layer capping structure into a patterned feature of the undercut photoresist structure.

In an embodiment of the method, an undercut photoresist structure is formed on the substrate, comprising depositing the organic light-emitting structure and the multi-layer capping structure into a patterned feature of the undercut photoresist structure in which forming an undercut photoresist structure comprises forming a bilayer photoresist structure; and forming an undercut in the bilayer photoresist structure.

In an aspect, a method of making an organic light-emitting diode includes:
i. forming a patterned photoresist structure on a substrate, comprising:
   a. depositing a first photoresist onto the substrate;
   b. baking the first photoresist at a temperature less than a glass transition temperature of the first organic light-emitting material;
   c. depositing a second photoresist onto the substrate;
   d. exposing the second photoresist to an exposure pattern; and
   e. developing the exposed second photoresist and the first photoresist;
ii. depositing a first organic light-emitting structure onto the substrate through the patterned photoresist structure; and
iii. depositing a multi-layer capping structure onto the first organic light-emitting structure, including depositing a first conductive layer and a second conductive layer such that each of the first and second conductive layers has a lateral extent greater than a lateral extent of the second organic light-emitting structure.

Embodiments can include one or more of the following features.

In an embodiment of the method, forming the patterned photoresist structure comprises forming the patterned photoresist structure on a substrate having a second organic light-emitting structure disposed thereon.

In an embodiment of the method, the first organic light-emitting structure is configured to emit light at a first wavelength and the second organic light emitting structure is configured to emit light at a second wavelength different from the first wavelength.

In an embodiment of the method, forming a patterned photoresist structure comprises forming an undercut photoresist structure.

In an embodiment of the method, forming a patterned photoresist structure comprises forming a bilayer photoresist structure; and forming an undercut in the bilayer photoresist structure.

In an embodiment of the method, depositing the second organic light-emitting structure by an evaporation process and depositing the multi-layer capping structure by a sputtering process.

In an embodiment of the method, the patterned photoresist structure is removed by exposure to a solvent after depositing the multi-layer capping structure.

In an embodiment of the method, the first photoresist is baked at a temperature of less than 75° C. for at least 1.5 hours.

In an embodiment of the method, the first and second photoresists are rehydrated for at least 1.5 hours prior to exposure.

In an embodiment of the method, the second photoresist is developed and exposed for less than 10 seconds.

In an embodiment of the method, the first photoresist is developed for less than 3 seconds.

### BRIEF DESCRIPTION OF DRAWINGS

FIG. 1 is a cross section of an example organic light emitting diode (OLED).

FIGS. 2A-2D are cross sections of fabrication of an OLED.

FIGS. 3A-3D are cross sections of fabrication of an OLED on a substrate that has an existing OLED fabricated thereon.

FIG. 4A is a flow chart of an OLED fabrication process.

FIG. 4B is a flow chart of a low temperature photolithography patterning process.

FIG. 5 is a diagram of a holographic display system.

### DETAILED DESCRIPTION

We describe here a process for fabricating high-resolution organic light emitting diode (OLED) structures suitable for high definition light field display technology, e.g., for applications in high resolution displays. The OLED structures can have sub-10 μm resolution, e.g., nanoscale resolution. The OLED structures are protected by a multilayer capping structure. High resolution OLEDs of multiple colors can be fabricated on a single substrate by way of a low temperature photolithography process that enables substrates already including OLEDs to be reprocessed for fabrication of additional OLEDs.

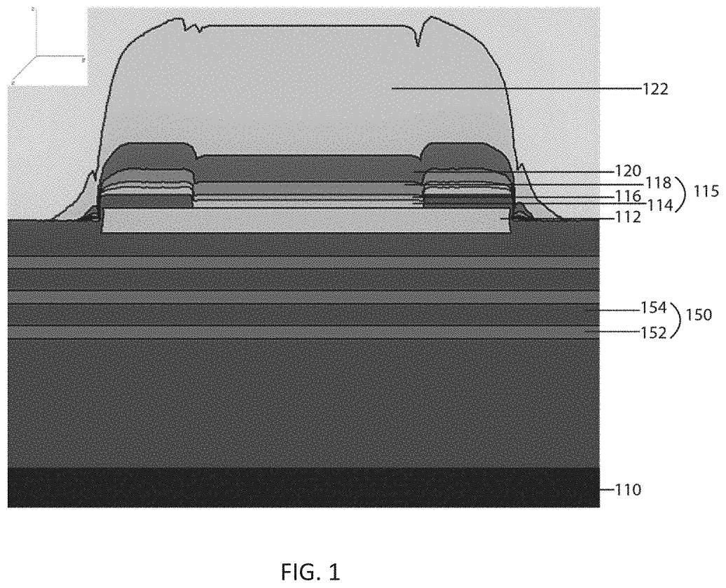

Referring to FIG. 1, an example OLED structure includes a light emitting structure 102 that includes one or more active layers that are configured to emit light at a certain wavelength. By OLED structure (sometimes also referred to as an OLED stack), we mean a set of active organic layers that, together with an anode and a cathode, form an OLED. As illustrated in FIG. 1, the OLED structure 100 is deposited on a clean substrate 110. In some examples, the substrate 110 can be transparent to light of the wavelength emitted by the OLED structure 100, e.g., for a bottom emission OLED. For instance, the substrate 110 can be indium tin oxide (ITO), epoxy, glass, or another transparent substrate. In some examples, such as for a top emission OLED, the substrate 110 is not necessarily transparent to light of the wavelength emitted by the OLED structure 100. For instance, the substrate 110 can be a silicon wafer.

The OLED structure 100 includes a first electrode 112 and a second electrode 120. A light emitting structure 115 is disposed between the first electrode 112 and the second electrode 120. The light emitting structure 115 includes active layers including a hole injection layer 114, a hole transport layer 116, an emission layer, an electron transport layer, and an electron injection layer 118. For illustrative purposes, the emission layer, electron transport layer, and electron injection layer are collectively represented as feature 118. The electrodes 112, 120 and light emitting structure 115 are covered by a capping layer 122. The lateral extent of the capping layer (meaning the extent of the capping layer in the x and y directions) is greater than the lateral extent of the electrodes 112, 114 and the light emitting structure. As discussed further below, the presence of a capping layer having a greater lateral extent than the other components of the OLED 100 can protect those components (e.g., the light emitting structure 115) from damage during subsequent fabrication processes, such as during fabrication of other OLEDs on the same substrate, e.g., OLEDs of other colors.

The first and second electrodes 112, 120 can be layers of a conductive material, such as aluminum, copper, gold, silver, indium tin oxide (ITO), a conductive polymer, or another conductive material. The first and second electrodes 112, 120 can have thicknesses of between about 50 nm and about 200 nm, e.g., 50 nm, 75 nm, 100 nm, 125 nm, 150 nm, 175 nm, or 200 nm. In a specific example, the first electrode is ITO at a thickness of about 100 nm, with a roughness of <20 nm pp and a transparency of >75% at the emission wavelength of the OLED structure. The first and second electrodes 112, 120 can be connected to control circuitry, e.g., integrated circuit pathways, for control of the operation of the OLED 100.

The layers of the light emitting structure 115, including the hole injection layer 114, hole transport layer 116, emission layer, electron transport layer, and electron injection layer are formed of organic materials. The hole injection layer 114, hole transport layer 116, emission layer, and electron transport layer have a composition and arrangement to enable recombination of electrons and holes in the emission layer, resulting in the emission of a photon. The wavelength of light emitted from the light emitting structure 102 of the OLED depends on factors such as the composition of the active layers and the geometry of the active layers.

In order to inject holes from electrodes to the corresponding HTL, very often a thin interlayer (IL) of some organic or inorganic material is inserted to ensure efficiency of hole injection from the electrodes to the HTL. HIL materials can broadly categorized into two groups-conducting polymers such as PEDOT:PSS and organic/inorganic interlayers which are strong electron acceptor. For conducting polymers, the work function of electrodes is being modified to match up more closely with the highest occupied molecular orbital (HOMO) of HTLs, thereby facilitating hole injection from the electrodes to the HTL by reducing the hole injection barrier. The electron acceptors work in a slightly different way. The lowest unoccupied molecular orbital (LUMO) of the electron-accepting material (HATCN, MoO₃, W₀₃) is usually close to the HOMO of typical HTLs which results in efficient electron transfer from HOMO of HTL to the LUMO of the electron accepting materials, thereby increasing mobile hole-transport in HTLs. Also, there may be charge transfer complex dipoles formed due to the proximity of the HOMO of HTLs and LUMO of electron-acceptors which also contributes to the charge transfer mechanism (results in an increase in current density).

Since organic/inorganic electron acceptors like HATCN and MoO₃ are used for inverted top emission with IZO electrode, for both sputtering protection and hole injection.

The hole injection layer 114 can be, for instance, 4,4′,4″-Tris[(3-methylphenyl)phenylamino]triphenylamine (m-MTDATA), MoOₓ, Woₓ, or another hole injecting material. The thickness of the hole injection layer 114 can be between about 20 nm and about 50 nm, e.g., 20 nm, 30 nm, 40 nm, or 50 nm.

The hole transport layer 116 can be, for instance, N,N′-Di(1-naphthyl)-N,N′-diphenyl-(1,1′-biphenyl)-4,4′-diamine (NPD), proprietary materials such as EDM's HT-081, or another hole transport material. The thickness of the hole transport layer 116 can be between about 10 nm and about 30 nm, e.g., 10 nm, 20 nm, or 30 nm.

The emission layer can be, e.g., Tris(8-hydroxyquinolinato)aluminium (Alq₃). The thickness of the emission layer can be between about 10 nm and about 30 nm, e.g., 10 nm, 20 nm, or 30 nm.

The electron transport layer can be, e.g., Alq₃, LiF, Cs₂Co₃, Liq, reduced MoOₓ and Woₓ, MnO₂, or another electron transport material. The thickness of the electron transport layer can be between about 20 nm and about 50 nm, e.g., 20 nm, 30 nm, 40 nm, or 50 nm.

The electron injection layer can be, e.g., LiF, CsCO₃, an LiF/Al combination, or another electron injection material. The thickness of the electron injection layer can be between about 50 nm and 150 nm, e.g., 50 nm, 75 nm, 100 nm, 125 nm, or 150 nm.

The capping layer 122 can be formed of a conductive material, such as aluminum, copper, gold, silver, indium tin oxide (ITO), or another conductive material. The material of the capping layer 122 can be robust against processes used for subsequent fabrication, such as fabrication of subsequent OLEDs. The capping layer 122 can be formed of a material that can be deposited in a directional deposition process, such as a sputtering process. The capping layer 122 can have a thickness of between about 300 nm and about 800 nm, such as 300 nm, 400 nm, 500 nm, 600 nm, 700 nm, or 800 nm.

In some examples, the capping layer 122 can include a single layer. In some examples, the capping layer 122 can include multiple layers, such as two layers, three layers, or more than three layers. For instance, in a specific example, the capping layer 122 can include a first layer of a metal, such as aluminum, and a second layer of ITO. The thicknesses of the first and second layers of the capping layer 122 can be substantially similar, or one of the layers can have a thickness that is significantly more than the thickness of the other one of the layers. For instance, the thickness of each of the first and second layers of the capping layer 122 can be between about 100 nm and about 700 nm, e.g., 100 nm, 200 nm, 300 nm, 400 nm, 500 nm, 600 nm, or 700 nm.

The lateral extent of the capping layer 122 (meaning the extent of the capping layer in the x and y directions) is greater than the lateral extent of the electrodes 112, 114 and the light emitting structure. This configuration means that the capping layer entirely covers the light emitting structure, enabling the capping layer to protect the light emitting structure to exposure from subsequent processing of the substrate.

In some examples, the OLED structure 100 can include a distributed Bragg reflector 150, e.g., formed on the substrate 110 or integral with the substrate 110. The distributed Bragg reflector 150 acts as a mirror, reflecting light emitted by the light emitting structure 115 away from the substrate 110 and toward the forward emission direction of the OLED structure 100, thereby increasing the efficiency of the OLED structure 100. The distributed Bragg reflector 150 can include alternating layers 152, 154 of two different materials, such as materials having different refractive indices. For instance, the alternating layers 152, 154 can be formed of silicon oxide (SiO₂) and titanium oxide (TiO₂), respectively. Other materials that can be used for the distributed Bragg reflector 150 can include materials that are transparent at a desired wavelength, e.g., the wavelength of the OLED emission (e.g., the visible wavelength range), e.g., SiₓN_{y}, GaAs, AlAs, AlInP, Al₂O₃, Ta₂O₅, TeO₂, Yb₂O₃, Y₂O₃, Nb₂O₅, MgO.

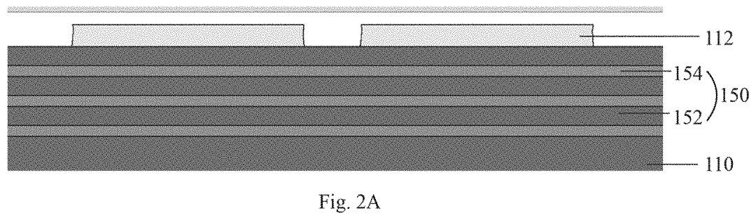

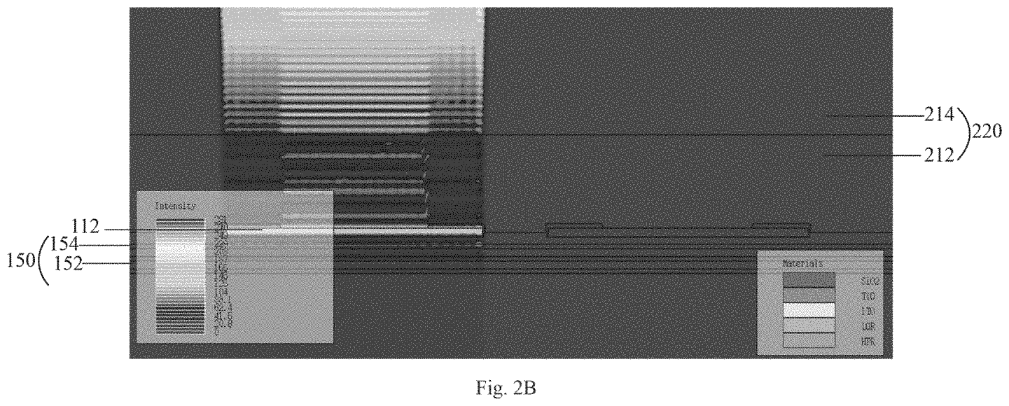

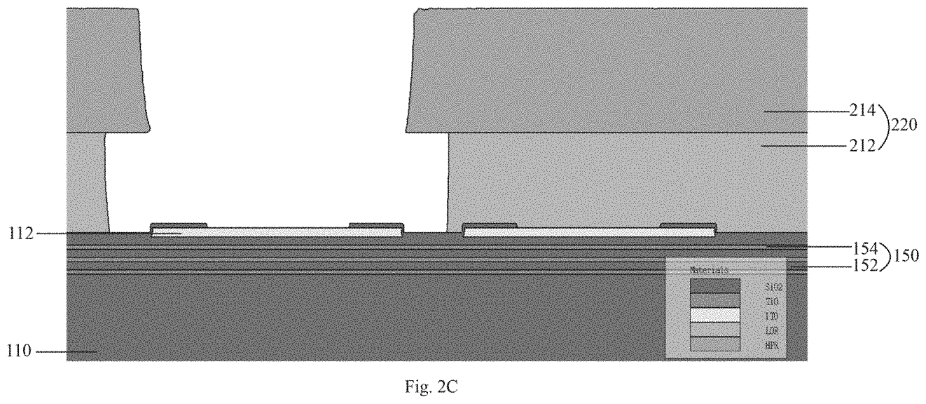

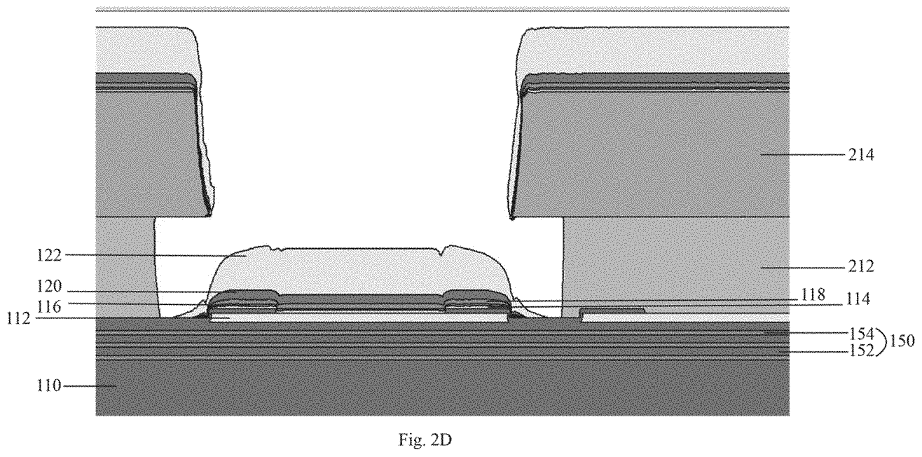

Referring to FIGS. 2A-2D, the OLED structure 100 can be fabricated using thin film deposition and patterning processes.

Referring specifically to FIG. 2A, the first electrode 112 is formed on the substrate 110. In some examples (e.g., as shown in FIG. 2A), the substrate 110 includes a distributed Bragg reflector 150; in some examples, no distributed Bragg reflector is present. The first electrode 112 can be formed using a thin film deposition process, such as evaporation or sputtering of a thin film of the conductive material of the electrode, followed by patterning, e.g., by photolithography. By evaporation, we mean a method of thin film deposition in which a source material (e.g., the material of the electrode 112) is evaporated in a vacuum, allowing vapor particles of the source material to travel directly to a target object (e.g., the substrate 110), where the particles condense back to a solid state.

In an example process for forming the first electrode 112 (sometimes also referred to as the anode 112), an adhesion layer is deposited on to the substrate, e.g., by spin coating. For instance, the adhesion layer can be hexamethyldisilazane (HDMS). The adhesion layer can be deposited at a temperature above room temperature, e.g., at a temperature of between 150° C. and 200° C., e.g., 150° C., 160° C., 170° C., 180° C., 190° C., or 200° C. Spin coating is a thin film deposition technique in which a small volume of a material (e.g., the material of the adhesion layer) is dispensed upon a substrate, and the substrate is rotated at high speed, e.g., several thousand revolutions per minute (rpm). In some examples, the substrate can be rotating already when the material is dispensed; in some examples, the material is dispensed first and then the rotation is initiated. The centrifugal force from the rotation spreads the material into a substantially uniform film on the substrate, and excess material is spun off of the surface. In some examples, the material dispensed onto the substrate includes a coating material in a solvent, and the solvent evaporates from the formed film during the rotation, stalling the thinning of the film. The stalled thinning enables the resulting film to be stable enough to avoid collapse during handling of the substrate after spin coating.

Photolithography is used to define and pattern the anode 112. Photolithography is a process in which a substrate is coated substantially uniformly with a thick, light-sensitive (e.g., ultraviolet (UV) light-sensitive) liquid called photoresist. Portions of the coated substrate are selected for exposure to light by careful alignment of a mask between a UV light source and the substrate. In transparent areas of the mask, light passes through and exposes the photoresist, causing the photoresist to harden and become impervious to certain etchants. A developer solution is then used to remove unexposed areas of the photoresist while leaving the hardened, exposed portions on the substrate. In some examples, a silicon nitride layer can be present below the layer of photoresist. After development of the photoresist, the substrate can be subjected to an etch process (e.g., a wet etch or a plasma dry gas etch) to remove portions of the silicon nitride layer that are not protected by the hardened portions of the photoresist, resulting in a pattern in silicon nitride that matches the design of the mask. The hardened photoresist can then be removed with an appropriate chemical.

In the example of FIG. 2A, a first resist bilayer is deposited, e.g., by spin coating the layers of the resist bilayer onto the adhesion layer. The resist bilayer can include a first layer of a first type of resist, such as a lift-off resist, e.g., LOR 5B, and a second layer of a second type of resist, such as a positive resist, e.g., HPR 504. The first and second layers of resist can have different thicknesses, e.g., the second layer can be thicker than the first layer. For instance, the first layer can have a thickness of between 200 nm and 800 nm, e.g., 200 nm, 500 nm, or 800 nm; and the second layer can have a thickness of between 1 μm and 1.5 μm, e.g., 1 μm, 1.25 μm, or 1.5 μm. The anode 112 is patterned, e.g., by way of photolithography, and each layer of the resist is developed by exposure to an appropriate developer. For instance, the top (second) resist bilayer can be an HPR 504 layer that is developed using DEV 354, and the bottom (first) resist layer can be an LORSB layer that is developed using MF319. The anode 112 is deposited through the patterned resist, e.g., by sputtering or another thin film deposition technique. The resist bilayer is then removed through a liftoff process. A lift-off process is a process by which a photoresist structure having a coating disposed thereon (e.g., the material of the anode 112) is removed from a substrate. The lift-off process removes the resist structure along with the coating disposed thereon, leaving behind the coating disposed directly on the substrate (e.g., the deposited anode structure).

Referring to FIG. 2B, the light emitting structure of the OLED structure 100 is also formed by thin film deposition and patterning processes, such as spin coating and photolithography. A template for the light emitting structure is formed on the anode 112 by deposition of a template material, such as silicon oxide or silicon nitride. For instance, the template material can be grown to a thickness of between about 50 nm and about 150 nm by an oxide growth process carried out at high temperature, such as a temperature of between about 200° C. and about 400° C., e.g., about 200° C., about 300° C., or about 400° C. An adhesion layer, such as a layer of HDMS, is formed onto the template layer, e.g., by spin coating.

A bilayer 220 of photoresist is formed on top of the adhesion layer, e.g., by spin coating. For instance, the resist bilayer can include a first layer 212 of a first type of resist, such as a lift-off resist, e.g., LOR 5B, and a second layer 214 of a second type of resist, such as a positive resist, e.g., HPR 504. The layers of resist can be deposited onto the adhesion layer by spin coating and then patterned and developed according to product specifications. The rainbow effect seen in FIG. 2B is due to light exposure to produce the pattern of the resist 220, each light intensity value represented by a different color.

The first layer 212 of resist (e.g., the lift-off resist) can be spin coated, e.g., to a thickness of between about 800 nm and about 1.3 μm, e.g., 800 nm, 900 nm, 1 μm, 1.1 μm, 1.2 μm, or 1.3 μm. In a specific example, the first layer 212 can be spin coated at 500 rpm for 10 seconds followed by spinning at 3000 rpm for 40 seconds. The first layer 212 of resist can then be baked for between 10 minutes and 30 minutes at a temperature of between about 150° C. and about 180° C., e.g., 150° C., 155° C., 160° C., 165° C., 170° C., 175° C., or 180° C.; followed by a cool down of between 5 minutes and 15 minutes, e.g., 5 minutes, 10 minutes, or 15 minutes.

The second layer 214 of resist (e.g., the positive resist) can then be deposited onto the first layer 212 by spin coating, e.g., to a thickness of between about 1 μm and about 1.5 μm, e.g., 1 μm, 1.1 μm, 1.2 μm, 1.3 μm, 1.4 μm, or 1.5 μm. In a specific example, the second layer 214 can be spin coated at 500 rpm for 10 seconds followed by spinning at 4000 rpm for 40 seconds. The second layer 214 of resist can then be soft baked for between 1 minute and 3 minutes at a temperature of between about 100° C. and about 130° C., e.g, 100° C., 105° C., 110° C., 115° C., 120° C., 125° C., or 130° C.; followed by a rehydration process of between 5 minutes and 30 minutes. The deposited resist bilayer 220 is patterned by photolithography and developed. For instance, the second layer 214 of resist can be HPR-504 that is developed using DEV 354 and the first layer 212 of resist can be LORSB that is developed using MF319.

Referring to FIG. 2C, the development of the resist bilayer forms an undercut 220. By an undercut, we mean a structure in which a bottom layer (here, the first resist layer 212) is recessed under a top layer (here, the second resist layer 214). The formation of this undercut plays a role in the formation of an effective capping layer. The size of the undercut can be controlled by the development of the resist bilayer 220, e.g., by the development time for each resist layer. For instance, the development time can be controlled to achieve a target length of the undercut region, such as a length between about 1 μm and about 3 μm, e.g., 1 μm, 2 μm, or 3 μm. For instance, the development time for the second resist layer 214 can be between about 5 seconds and about 20 seconds, e.g., 5 seconds, 10 seconds, 15 seconds, or 20 seconds; and the development time for the first resist layer 212 can be between about 1 second and about 5 seconds, e.g., 1 second, 2 seconds, 3 seconds, 4 seconds, or 5 seconds. The organic layers of the light emitting structure of the OLED structure are then deposited through the patterned resist bilayer 220, e.g., by evaporation. For instance, successive evaporation processes can be performed to deposit the hole injection layer 114, the hole transport layer 116, the emission layer, the electron transport layer, and the electron injection layer 118.

Referring to FIG. 2D, the cathode and a protective capping layer 122 is then deposited through the patterned resist bilayer 220. For instance, the capping layer 122 can be deposited by sputtering. In some examples, the capping layer 122 can include multiple layers, such as a layer of aluminum and a layer of ITO, each of which is deposited by sputtering. A multi-layer capping structure provides protection to the organics while including different materials, which reduces the impact of stress, therefore enabling capping layer cracking to be reduced. Sputtering is a thin film deposition process in which a target material (here, the material of the capping layer) and the substrate are placed in a vacuum chamber. A voltage is applied between the target material and the substrate, e.g., making the target material the cathode and the substrate the anode. Plasma is created in the vacuum chamber by ionizing a sputtering gas, such as an inert gas. The sputtering gas covers the target material and sputters off material, which is then deposited onto the substrate. Sputtering enables deposition of the capping layer into the controlled undercut region. The presence of the sputtered capping layer 122 in the undercut region means that the capping layer has a lateral extent greater than the lateral extent of the light emitting structure, such that the capping layer completely and protects the organic layers of the light emitting structure. In addition, capping layer material deposited into the undercut region has good adhesion in the undercut region, helping to prevent damaging solvent penetration through to the organic layers of the light emitting structure during subsequent processing.

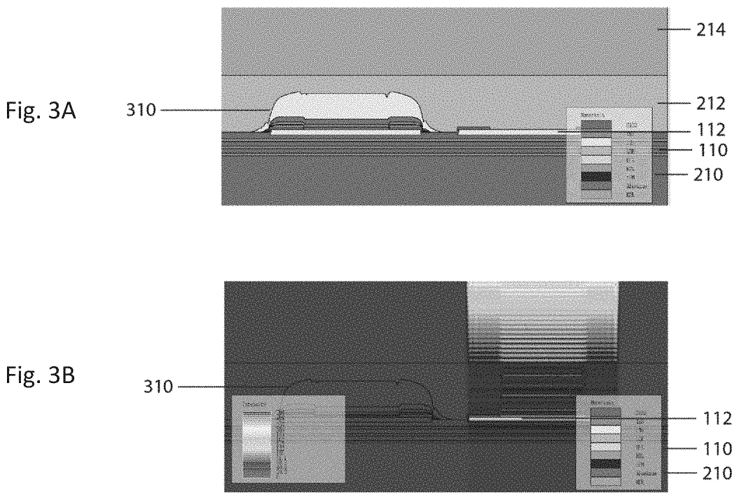

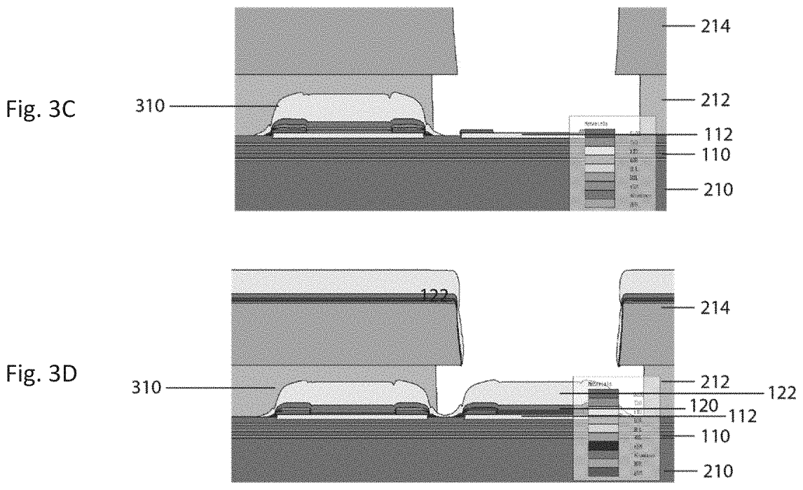

Referring to FIGS. 3A-3D, in some examples, the processes described here can be used to fabricate multiple, high resolution OLEDs on a substrate in successive fabrication processes. After an OLED has been fabricated on a substrate, subsequent OLED fabrication can occur at lower baking temperatures so as not damage the organic layers of the first deposited OLED structure. For instance, this process enables multiple sets of OLEDs, each having a corresponding emission wavelength, to be fabricated on a single substrate, thereby enabling the manufacture of a single-substrate, multi-color, OLED-based display.

Referring specifically to FIG. 3A, in a first process step, two layers of resist, a first layer 212 (e.g., a lift-off resist such as LOR 10B) and a second layer 214 (e.g., a positive resist such as HPR 504), are formed on a substrate 110 with an existing OLED 310 using a low temperature photoresist patterning process. Prior to resist layer formation, an adhesion layer, such as HDMS, is deposited on the anode 112, e.g., using a spin coat process, such as described above with respect to FIG. 2A.

A resist bilayer is then formed on the substrate. Specifically, the first layer 212 of resist, e.g., LOR 10B, is deposited, e.g., spin coated, onto the adhesion layer. For instance, LOR 10B can be spun onto the substrate at 500 rpm for 10 seconds, followed by spinning at 3000 rpm for 40 seconds. The first layer 212 of resist is then baked at a temperature that is low enough to not damage the active layers of the existing OLED 310, e.g., at a temperature that is less than a glass transition temperature of one or more of the materials of the active layers of the existing OLED 310. For instance, the first layer 212 of resist can be baked at a temperature of between 50° C. and 90° C., e.g., between 50° C. and 75° C., e.g., 50° C., 55° C., 60° C., 65° C., 70° C., 75° C., 80° C., 85° C., or 90° C. This temperature can be significantly less than a temperature prescribed by the product specification for the resist, e.g., between 30% and 65% of the prescribed temperature (in degrees Celsius). The baking of the bottom layer 212 of resist can be carried out for a time longer than the product specification, e.g., such that the bottom layer 212 of resist is exposed to a sufficient thermal load despite the lower baking temperature. For instance, the bottom layer 212 of resist can be baked for between 60 minutes and 120 minutes, e.g., 60 minutes, 75 minutes, 90 minutes, 105 minutes, or 120 minutes. After baking, the bottom layer 212 of resist can be cooled, e.g., for up to 15 minutes.

A second layer 214 of a different resist, e.g., HPR 504, is deposited, e.g., spin coated, onto the baked first layer 212. For instance, HPR 504 can be spun at 500 rpm for 10 seconds, followed by spinning at 4000 rpm for 4 seconds. The second layer 214 is then baked at a temperature that is low enough to not damage the active layers of the existing OLED 310, e.g., at a temperature that is less than a glass transition temperature of one or more of the materials of the active layers of the existing OLED 310. For instance, the second layer 214 of resist can be baked at a temperature of between 50° C. and 100° C., e.g., 50° C., 55° C., 60° C., 65° C., 70° C., 75° C., 80° C., 85° C., 90° C., 95° C., or 100° C. This temperature can be significantly less than a temperature prescribed by the product specification for the resist, e.g., between 40% and 90% of the prescribed temperature (in degrees Celsius). The baking of the bottom layer 212 of resist can be carried out for a time longer than the product specification, e.g., such that the bottom layer 212 of resist is exposed to a sufficient thermal load despite the lower baking temperature. For instance, the bottom layer 212 of resist can be baked for between 2 minutes and 8 minutes, e.g., 2 minutes, 4 minutes, 6 minutes, or 8 minutes. After baking, the bottom layer 212 of resist can be rehydrated for at least 90 minutes, e.g., between 90 minutes and 3 hours, e.g., 90 minutes, 2 hours, 2.5 hours, or 3 hours.

Referring to FIGS. 3B-3D, patterning, development, and deposition of the light emitting structure and capping layer proceed generally similarly to the processes described with respect to FIGS. 2B-2D. The resulting substrate has a first OLED 310 and a second OLED 312, e.g., OLEDs of different colors, each having capping layers formed thereover.

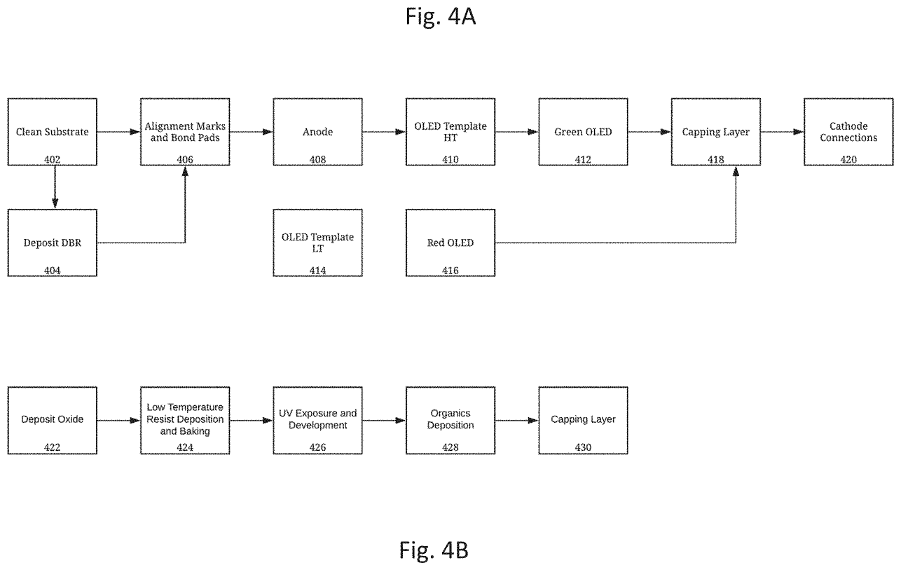

FIG. 4A shows an example process for manufacturing an OLED. This process flow is based on a bottom emission OLED design to avoid sputtering damage to the organics during the deposition of the ITO anode. The roughness of the Al cathode plays a non-major role in the functionality of the OLED in this design. A first OLED is patterned through photolithography with a conventional photoresist bilayer, using development specifications (e.g., time and temperature) as prescribed by the manufacturer. To avoid damaging the OLED materials during fabrication of subsequent OLEDs on the same substrate, the bilayer recipe is modified so the baking steps are carried out at lower temperatures and for longer times.

The process begins with a clean substrate 402, the square dimensions can be 1-2″, e.g., 1″, 1.25″, 1.5″, 2″. The material can be fused silica material, glass or other transparent material. A distributed Bragg reflector (DBR) is deposited 404—alternating layers of dielectric material. For instance, the alternating layers can be formed of silicon oxide (SiO₂) and titanium oxide (TiO₂), respectively. Other materials that can be used for the distributed Bragg reflector 150 can include, e.g., SiₓN_{y}, GaAs, AlAs, AlInP, Al₂O₃, Ta₂O₅, TeO₂, Yb₂O₃, Y₂O₃, Nb₂O₅, MgO. The materials could be any transparent materials in the visible wavelength range. Alignment marks and bond pads 406 are then deposited. ITO patterning for the anode 408 is conducted through photolithography using the high temperature process. The OLED template is patterned 410 using the high temperature process. The active layers of a first OLED are deposited. In the present embodiment, the first OLED is a green OLED 412. Once the active layers and Al cathode have been deposited by way of evaporation, an AUITO capping layer 418 is applied by way of sputtering. A second OLED template is patterned using photolithography.

In an embodiment of the disclosure, the patterning of the second OLED template consists of a low temperature photolithography process. FIG. 4B illustrates a low temperature photoresist patterning technique for a substrate with an OLED previously deposited thereon for OLED structures for a high-definition light field display. Following the deposition of the first OLED structure 412 and first OLED capping layer 418 as outline in FIG. 4A, a SiO₂ layer is deposited 422.

The low temperature resist deposition and baking process 424 includes an HMDS adhesion layer followed by a cool down of about 10 min to 12 min, e.g., about 10, 11 min, or 12 min. A first resist layer of LOR 10B is spin coated on to the substrate. The spread is spun at 500 rpm for about 10 seconds followed by a spin at 3000 rpm from 40 to 45 seconds, e.g., 40 seconds, 41 seconds, 42 seconds, 43 seconds, 44 seconds, or 45 seconds. The LOR 10B layer is baked for at least 90 minutes at a temperature in the range of 75° C. to 80° C., e.g., 75° C., 76° C., 77° C., 78° C., 79° C., and 80° C., followed by a 10 to 12 min cool down, e.g., 10 min, 11 min, or 12 min. A second resist layer of HPR 504 is spin coated onto the first resist layer. The spread is spun at 500 rpm for 10 seconds followed by a spin at 4000 rpm for 40 seconds. The HPR 504 layer is baked for 4 minutes at 80° C. followed by a 15 min rehydration process.

The present embodiment then describes UV exposure and development 426. The UV exposure time is between 2.5 and 2.7 seconds, e.g., 2.5 seconds, 2.6 seconds, or 2.7 seconds at 62.9 E.F. The second resist layer, HPR 504, is developed using DEV 354 for 8 s. The first resist layer, LOR 10B, is developed using MF-319 for 3 s.

The organics for the second OLED are then deposited 428 by way of evaporation. The capping layer is deposited 430 by way of sputtering. The first capping layer material, Al, is deposited with a target thickness of 280 nm at a deposition rate of 13.4 nm/min. The second capping layer material, ITO, is deposited with a target thickness of 250 nm for a deposition time of 32 min 30 seconds, at a deposition pressure of 6.0×10⁻³ Torr.

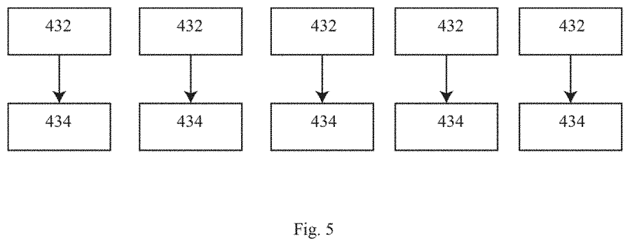

Referring to FIG. 5, an example holographic display system incorporates OLEDs such as those described here. The light source includes an array of OELD structures 432 with a pixel size of sub 10 μm. The OLED array 432 combined with a directional optical layer or optical guiding surface 434 create a directional pixel array system resulting in a high angular resolution, wide field of view, multiple view display.

To create a three-dimensional light-field display, each of the light beams propagate through one or more directional optical layer or optical guiding surfaces 434; the directional optical guiding surface 434 directs the light in a single direction. The directional optical guiding surface 434 can be any type of dielectric surface, such as a lens, lens-like surface, or a metasurface with periodic or non-periodic gratings. Multiple viewers can observe the same three-dimensional display screen and be presented with differing light beams, directed by the directional optical guiding surface. For example, where a first viewer located at a first angle can view a first directional pixel directed towards the first viewer, a second viewer at a second angle can view a second directional pixel directed towards the second viewer. The directional optical guiding surface 434 guides the light beams emitted from each of the RGB subpixels in a first directional pixel in the same direction as the RGB subpixels in a second directional pixel, and so forth.

The increased number of distinct light emission directions enables the creation of high angular resolution displays with improved depth of field.

A number of embodiments have been described. Nevertheless, it will be understood that various modifications may be made without departing from the spirit and scope of the invention. For example, some of the steps described above may be order independent, and thus can be performed in an order different from that described.

Other implementations are also within the scope of the following claims.

What is claimed is:

1. An organic light-emitting diode comprising:
a substrate;
a first electrode disposed on the substrate;
an organic light-emitting structure disposed on the first electrode;
a multi-layer capping structure disposed over the organic light-emitting material, the multi-layer capping structure including a first conductive layer and a second conductive layer each having a lateral extent greater than a lateral extent of the organic light-emitting material.

2. The organic light-emitting diode of claim 1, in which the organic light-emitting structure comprises one or more layers of light-emitting material.

3. The organic light-emitting diode of claim 1, in which the first conductive layer of the capping structure comprises aluminum.

4. The organic light-emitting diode of claim 1, in which the second conductive layer of the capping structure comprises indium tin oxide (ITO).

5. The organic light-emitting diode of claim 1, comprising a second electrode disposed between the organic light-emitting structure and the capping structure.

6. The organic light-emitting diode of claim 1, in which the substrate is formed of a material transparent to one or more wavelengths of light emitted by the organic light-emitting structure.

7. A method of making an organic light-emitting diode, the method comprising:
forming an electrode on a substrate;
depositing an organic light-emitting structure on the first electrode; and
depositing a multi-layer capping structure over the organic light emitting structure, including depositing a first conductive layer and a second conductive layer such that each of the first and second conductive layers has a lateral extent greater than a lateral extent of the organic light-emitting structure.

8. The method of claim 7, in which depositing a first conductive layer comprises depositing a layer of aluminum and in which depositing a second conductive layer comprises depositing a layer of indium tin oxide (ITO) onto the layer of aluminum.

9. The method of claim 7, in which depositing a multi-layer capping structure comprises depositing the first and second conductive layers by a sputtering process.

10. The method of claim 7, comprising depositing the organic light-emitting structure by an evaporation process.

11. The method of claim 7, comprising patterning the organic light-emitting structure.

12. The method of claim 7, comprising depositing a second electrode on the organic light-emitting structure.

13. The method of claim 12, comprising depositing the second electrode by an evaporation process.

14. The method of claim 7, comprising forming an undercut photoresist structure on the substrate, and comprising depositing the organic light-emitting structure and the multi-layer capping structure into a patterned feature of the undercut photoresist structure.

15. The method of claim 14, in which forming an undercut photoresist structure comprises forming a bilayer photoresist structure; and forming an undercut in the bilayer photoresist structure.

16. A method of making an organic light-emitting diode, the method comprising:
forming a patterned photoresist structure on a substrate, comprising:
depositing a first photoresist onto the substrate;
baking the first photoresist at a temperature less than a glass transition temperature of the first organic light-emitting material;
depositing a second photoresist onto the substrate;
exposing the second photoresist to an exposure pattern; and
developing the exposed second photoresist and the first photoresist;
depositing a first organic light-emitting structure onto the substrate through the patterned photoresist structure; and
depositing a multi-layer capping structure onto the first organic light-emitting structure, including depositing a first conductive layer and a second conductive layer such that each of the first and second conductive layers has a lateral extent greater than a lateral extent of the second organic light-emitting structure.

17. The method of claim 16, in which forming the patterned photoresist structure comprises forming the patterned photoresist structure on a substrate having a second organic light-emitting structure disposed thereon.

18. The method of claim 16, in which the first organic light-emitting structure is configured to emit light at a first wavelength and the second organic light emitting structure is configured to emit light at a second wavelength different from the first wavelength.

19. The method of claim 16, in which forming a patterned photoresist structure comprises forming an undercut photoresist structure.

20. The method of claim 19, in which forming an undercut photoresist structure comprises forming a bilayer photoresist structure; and forming an undercut in the bilayer photoresist structure.

21. The method of claim 16, comprising depositing the second organic light-emitting structure by an evaporation process and depositing the multi-layer capping structure by a sputtering process.

22. The method of claim 16, comprising removing the patterned photoresist structure by exposure to a solvent after depositing the multi-layer capping structure.

23. The method of claim 16, comprising baking the first photoresist at a temperature of less than 75° C. for at least 1.5 hours.

24. The method of claim 16, comprising rehydrating the first and second photoresists for at least 1.5 hours prior to exposure.

25. The method of claim 16, comprising developing the exposed second photoresist for less than 10 seconds.

26. The method of claim 16, comprising developing the first photoresist for less than 3 seconds.
